(19) United States
(12) Patent Application Publication
(10) Pub. No.: US 2013/0168614 A1
(43) Pub. Date: Jul. 4, 2013

(54) NICKEL ALLYL AMIDINATE PRECURSORS FOR DEPOSITION OF NICKEL-CONTAINING FILMS

(71) Applicant: Clément LANSALOT-MATRAS, Tsukuba (JP)

(72) Inventor: Clément LANSALOT-MATRAS, Tsukuba (JP)

(73) Assignee: L'Air Liquide Société Anonyme pour ''Etude et l'Exploitation des Procédés Georges Claude, Paris (FR)

(21) Appl. No.: 13/339,530

(22) Filed: Dec. 29, 2011

(51) Int. Cl. C23C 16/44; C23C 16/50; H01B 1/08; C07F 15/04; H01B 1/06; C22C 19/03; C23C 16/455; C23C 16/56

(52) U.S. Cl. 252/519.1; 427/248.1; 427/255.28; 427/569; 556/35; 556/36; 420/441

(57) ABSTRACT

Disclosed are nickel allyl amidinate precursors having the formula:

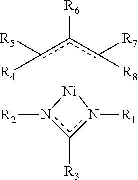

wherein each of R₁, R₂, R₃, R₄, R₅, R₆, R₇, and R₈ are independently selected from H; a C1-C4 linear, branched, or cyclic alkyl group, a C1-C4 linear, branched, or cyclic alkylsilyl group (mono, bis, or tris alkyl); a C1-C4 linear, branched, or cyclic alkylamino group; or a C1-C4 linear, branched, or cyclic fluoroalkyl group. Also disclosed are methods of synthesizing and using the disclosed precursors to deposit nickel-containing films on one or more substrates via a vapor deposition process.

### TECHNICAL FIELD

Disclosed are nickel allyl amidinate precursors. Also disclosed are methods of synthesizing and using the disclosed precursors to deposit nickel-containing films on one or more substrates via vapor deposition processes.

### BACKGROUND

In the semiconductor industry, there is an ongoing interest in the development of volatile metal precursors for the growth of thin metal films by Chemical Vapor Deposition (CVD) and Atomic Layer Deposition (ALD) for various applications. CVD and ALD are the main gas phase chemical processes used to control deposition at the atomic scale and create extremely thin and conformal coatings. In a typical CVD process, the wafer is exposed to one or more volatile precursors, which react and/or decompose on the substrate surface to produce the desired deposit. ALD processes are based on sequential and saturating surface reactions of alternatively applied precursors, separated by inert gas purging.

During the fabrication of a transistor, silicide layers may be used to improve the conductivity of polysilicon. For instance nickel and cobalt silicide (NiSi, CoSi₂) may be used as a contact in the source and drain of the transistor to improve conductivity. The process to form a metal silicide begins by the deposition of a thin pure metal layer on the polysilicon. The metal and a portion of the polysilicon are then alloyed together to form the metal silicide layer. Physical deposition methods were typically used for the deposition of pure layer of cobalt. However, as the size of the devices is decreasing, physical deposition methods no longer satisfy the requirements in term of conformality.

Nickel oxide (NiO) has received attention in the semiconductor industry. The resistance switching characteristics of NiO thin films show its potential applications for the next generation nonvolatile resistive random access memory (ReRAM) devices.

In order to obtain high-purity, thin, and high-performance solid materials on the wafer, the precursors require high purity, good thermal stability, high volatility and appropriate reactivity. Furthermore the precursors should vaporize rapidly and at a reproducible rate, conditions usually met by liquid precursors, but not by solid precursors (See R. G. Gordon et al., FutureFab International, 2005, 18, 126-128).

Bis aminoalkoxide nickel precursors have been successfully used for the preparation of NiO films by CVD (Surface & Coatings Technology 201 (2007) 9252-9255) and by ALD (J. Vac. Sci. Technol. A 23, 4, 2005). Those precursors could also be used for the preparation of pure nickel films using ammonia as reducing agent in thermal mode. W H Kim, ADMETA 2009:19th Asian Session 102-103. Ni films have also been successfully deposited using these molecules with hydrogen or ammonia in PEALD. H B R Lee, ADMETA 2009:19th Asian Session 62-63.

Bis amidinate nickel precursors have not been successfully used because they are unstable solids. As shown in FIG. 1, the precursors leave a greater than 15% residual mass during thermogravimetric analysis and undergo two phase changes at approximately 65° C. and approximately 200° C., respectively.

WO2010/052672 broadly discloses a method to form metal containing films using heteroleptic metal precursors having an allyl or cyclopentene ligand combined with an amidinate, guanidinate, diketonate, beta-enaminoketonate, beta-diketiminate, or cyclopentadienyl ligand. No exemplary nickel precursors are disclosed. In particular, liquid and volatile allyl beta-diketiminate palladium precursors are described.

EP1884517 broadly discloses organometallic compounds containing an alkenyl ligand for use as vapor deposition precursors. The exemplary nickel precursor disclosed in Examples 3 and 4 is ((iPr)₂—N—CH₂—C(H)═C(Et)—CH₂)Ni(pyrazo)(Bz)(CO) in 2-methoxyethoxy acetate.

A need remains for nickel precursors suitable for CVD or ALD using hydrogen as reducing agent. Desirable properties of the metal precursors for these applications are: i) liquid form or low melting point solid; ii) high volatility; iii) sufficient thermal stability to avoid decomposition during handling and delivery; and iv) appropriate reactivity during CVD/ALD process.

### SUMMARY

Disclosed are nickel-containing precursors having the formula:

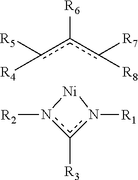

wherein each of R₁, R₂, R₃, R₄, R₅, R₆, R₇, and R₈ are independently selected from H; a C1-C4 linear, branched, or cyclic alkyl group; a C1-C4 linear, branched, or cyclic alkylsilyl group (mono, bis, or tris alkyl); a C1-C4 linear, branched, or cyclic alkylamino group; or a C1-C4 linear, branched, or cyclic fluoroalkyl group. The disclosed nickel-containing precursors may further include one or more of the following aspects:
the nickel-containing precursor being η3-allyl N,N′-dimethylacetamidinate;
the nickel-containing precursor being η3-allyl N,N′-diethylacetamidinate;
the nickel-containing precursor being η3-allyl N,N′-diisopropylacetamidinate;
the nickel-containing precursor being η3-allyl N,N′-di-n-propylacetamidinate;
the nickel-containing precursor being η3-allyl N,N′-di-tertbutylacetamidinate;
the nickel-containing precursor being η3-allyl N,N′-ethyl,tertbutylacetamidinate;
the nickel-containing precursor being η3-allyl N,N′-ditrimethylsilylacetamidinate;
the nickel-containing precursor being η3-allyl N,N′-diisopropylguanidinate;
the nickel-containing precursor being η3-allyl N,N′-diisopropylformidinate;
the nickel-containing precursor being η3-1-methylallyl N,N′-dimethylacetamidinate;
the nickel-containing precursor being η3-1-methylallyl N,N′-diethylacetamidinate;
the nickel-containing precursor being η3-1-methylallyl N,N′-diisopropylacetamidinate;
the nickel-containing precursor being η3-1-methylallyl N,N′-di-n-propylacetamidinate;
the nickel-containing precursor being η3-1-methylallyl N,N′-di-tertbutylacetamidinate;
the nickel-containing precursor being η3-1-methylallyl N,N′-ethyl,tertbutylacetamidinate;
the nickel-containing precursor being η3-1-methylallyl N,N′-ditrimethylsilylacetamidinate;
the nickel-containing precursor being η3-1-methylallyl N,N′-diisopropylguanidinate;
the nickel-containing precursor being η3-1-methylallyl N,N′-diisopropylformidinate;
the nickel-containing precursor being η3-2-methylallyl N,N′-dimethylacetamidinate;
the nickel-containing precursor being η3-2-methylallyl N,N′-diethylacetamidinate;
the nickel-containing precursor being η3-2-methylallyl N,N′-diisopropylacetamidinate;
the nickel-containing precursor being η3-2-methylallyl N,N′-di-n-propylacetamidinate;
the nickel-containing precursor being η3-2-methylallyl N,N′-di-tertbutylacetamidinate;
the nickel-containing precursor being η3-2-methylallyl N,N′-ethyl,tertbutylacetamidinate;
the nickel-containing precursor being η3-2-methylallyl N,N′-ditrimethylsilylacetamidinate;
the nickel-containing precursor being η3-2-methylallyl N,N′-diisopropylguanidinate; and
the nickel-containing precursor being η3-2-methylallyl N,N′-diisopropylformidinate.

Also disclosed are processes for the deposition of nickel-containing films on one or more substrates. At least one nickel-containing precursor is introduced into a reactor having at least one substrate disposed therein. At least part of the nickel-containing precursor is deposited onto the at least one substrate to form the nickel-containing film. The at least one nickel-containing precursor has the following formula:

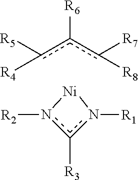

wherein each of R₁, R₂, R₃, R₄, R₅, R₆, R₇, and R₈ are independently selected from H; a C1-C4 linear, branched, or cyclic alkyl group; a C1-C4 linear, branched, or cyclic alkylsilyl group (mono, bis, or tris alkyl); a C1-C4 linear, branched, or cyclic alkylamino group; or a C1-C4 linear, branched, or cyclic fluoroalkyl group. The disclosed processes may further include one or more of the following aspects:
introducing at least one reactant into the reactor;
the reactant being selected from the group consisting of H₂, NH₃, SiH₄, Si₂H₆, Si₃H₈, SiH₂Me₂, SiH₂Et₂, N(SiH₃)₃, hydrogen radicals thereof; and mixtures thereof;
the reactant being selected from the group consisting of: O₂, O₃, H₂O, NO, N₂O, oxygen radicals thereof; and mixtures thereof;
the nickel-containing precursor and the reactant being introduced into the reactor substantially simultaneously;
the reactor being configured for chemical vapor deposition;
the reactor being configured for plasma enhanced chemical vapor deposition;
the nickel-containing precursor and the reactant being introduced into the chamber sequentially;
the reactor being configured for atomic layer deposition;
the reactor being configured for plasma enhanced atomic layer deposition;
the nickel-containing precursor being η3-allyl N,N′-dimethylacetamidinate;
the nickel-containing precursor being η3-allyl N,N′-diethylacetamidinate;
the nickel-containing precursor being η3-allyl N,N′-diisopropylacetamidinate;
the nickel-containing precursor being η3-allyl N,N′-di-n-propylacetamidinate;
the nickel-containing precursor being η3-allyl N,N′-di-tertbutylacetamidinate;
the nickel-containing precursor being η3-allyl N,N′-ethyl,tertbutylacetamidinate;
the nickel-containing precursor being η3-allyl N,N′-ditrimethylsilylacetamidinate;
the nickel-containing precursor being η3-allyl N,N′-diisopropylguanidinate;
the nickel-containing precursor being η3-allyl N,N′-diisopropylformamidinate;
the nickel-containing precursor being η3-1-methylallyl N,N′-dimethylacetamidinate;
the nickel-containing precursor being η3-1-methylallyl N,N′-diethylacetamidinate;
the nickel-containing precursor being η3-1-methylallyl N,N′-diisopropylacetamidinate;
the nickel-containing precursor being η3-1-methylallyl N,N′-di-n-propylacetamidinate;
the nickel-containing precursor being η3-1-methylallyl N,N′-di-tertbutylacetamidinate;
the nickel-containing precursor being η3-1-methylallyl N,N′-ethyl,tertbutylacetamidinate;
the nickel-containing precursor being η3-1-methylallyl N,N′-ditrimethylsilylacetamidinate;
the nickel-containing precursor being η3-1-methylallyl N,N′-diisopropylguanidinate;
the nickel-containing precursor being η3-1-methylallyl N,N′-diisopropylformamidinate;
the nickel-containing precursor being η3-2-methylallyl N,N′-dimethylacetamidinate;
the nickel-containing precursor being η3-2-methylallyl N,N′-diethylacetamidinate;
the nickel-containing precursor being η3-2-methylallyl N,N′-diisopropylacetamidinate;
the nickel-containing precursor being η3-2-methylallyl N,N′-di-n-propylacetamidinate;
the nickel-containing precursor being η3-2-methylallyl N,N′-di-tertbutylacetamidinate;
the nickel-containing precursor being η3-2-methylallyl N,N′-ethyl,tertbutylacetamidinate;
the nickel-containing precursor being η3-2-methylallyl N,N′-ditrimethylsilylacetamidinate
the nickel-containing precursor being η3-2-methylallyl N,N′-diisopropylguanidinate;
the nickel-containing precursor being η3-2-methylallyl N,N′-diisopropylformamidinate;
annealing the nickel-containing film;
the annealed nickel-containing film is an approximately 100% pure Ni film; and
the pure Ni film containing no carbon or nitrogen.

Also disclosed are nickel-containing films deposited by any of the processes disclosed above in which the bulk resistivity is approximately 7 μohm·cm to approximately 70 μohm·cm at room temperature.

### Notation and Nomenclature

Certain abbreviations, symbols, and terms are used throughout the following description and claims, and include:

The standard abbreviations of the elements from the periodic table of elements are used herein. It should be understood that elements may be referred to by these abbreviations (e.g., Ni refers to nickel, Co refers to cobalt, etc.).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

The term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group; the abbreviation “Bu” refers to butyl; the abbreviation “tBu” refers to tert-butyl; the abbreviation “sBu” refers to sec-butyl; the abbreviation “acac” refers to acetylacetonato/acetylacetone (acetylacetonato being the ligand and acetylacetonate being a molecule), with acetylacetonate being illustrated below; the abbreviation “tmhd” refers to 2,2,6,6-tetramethyl-3,5-heptadionato; the abbreviation “od” refers to 2,4-octadionato; the abbreviation “mhd” refers to 2-methyl-3,5-hexadinonato; the abbreviation “tmod” refers to 2,2,6,6-tetramethyl-3,5-octanedionato; the abbreviation “ibpm” refers to 2,2,6-trimethyl-3-5-heptadionato; the abbreviation “hfac” refers to hexafluoroacetylacetonato; the abbreviation “tfac” refers to trifluoroacetylacetonato; the abbreviation “Cp” refers to cyclopentadienyl; the abbreviation “Cp*” refers to pentamethylcyclopentadienyl; the abbreviation “op” refers to (open)pentadienyl; the abbreviation “cod” refers to cyclooctadiene; the abbreviation “dkti” refers to diketiminate/diketimine (ligand/molecule), with diketiminate illustrated below (with R¹ being the R ligand connected to the C at the apex of the dkti ligand in the structure below, each R² independently being the R ligand connected to the C in the dkti chain, and each R³ independently being the R ligand connected to the N; for example HC(C(Me)N(Me))₂); the abbreviation “emk” refers to enaminoketonate/enaminoketone (ligand/molecule), with enaminoketonate illustrated below (where each R is independently selected from H and a C1-C6 linear, branched, or cyclic alkyl or aryl group) (emk is also sometimes referred to as ketoiminate/ketoimine); the abbreviation “amd” refers to amidinate, illustrated below (with R¹ being the R ligand connected to C in the structure below and each R² independently being the R ligand connected to each N; for example MeC(N(SiMe₃)₂); the abbreviation “formd” refers to formamidinate, illustrated below; the abbreviation “dab” refers to diazabutadiene, illustrated below (where each R is independently selected from H and a C1-C6 linear, branched, or cyclic alkyl or aryl group).

For a better understanding, the generic structures of some of these ligands are represented below. These generic structures may be further substituted by substitution groups, wherein each R is independently selected from: H; a C1-C6 linear, branched, or cyclic alkyl or aryl group; an amino substituent such as NR₁R₂ or NR₁R₂R₃, with MNR₁R₂R₃ illustrated below, where each R₁, R₂ and R₃ is independently selected from H and a C1-C6 linear, branched, or cyclic alkyl or aryl group; and an alkoxy substituent such as OR, or OR₄R₅, with MOR₄R₅ illustrated below, where each R, R₄ and R₅ is independently selected from H and a C1-C6 linear, branched, or cyclic alkyl or aryl group.

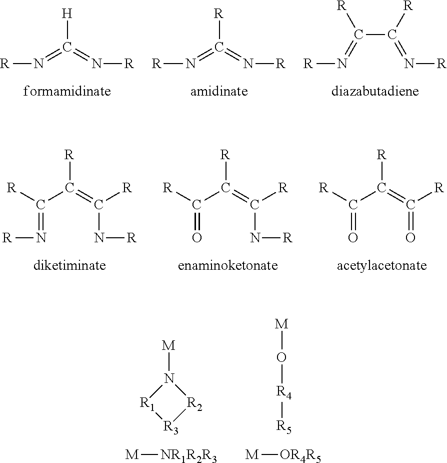

### BRIEF DESCRIPTION OF THE FIGURES

For a further understanding of the nature and objects of the present invention, reference should be made to the following detailed description, taken in conjunction with the accompanying figure wherein:

FIG. 1 is a ThermoGravimetric Analysis (TGA) and Differential Thermal Analysis (DTA) graph demonstrating the percentage of weight loss (TGA) or the differential temperature (DTA) with increasing temperature of Ni(N^{iPr}-amd)₂;

FIG. 2 is a TGA and DTA graph of Ni(2-Meallyl)(N^{iPr}-amd) in atmospheric and dynamic vacuum (2000 Pa) conditions;

FIG. 3 is a 1HNMR spectrum of Ni(2-Meallyl)(N^{iPr}-amd);

FIG. 4 is a Plasma Enhanced Atomic Layer Deposition (PEALD) saturation curve showing the growth per cycle (GPC) of the Ni film versus Ni(2-Meallyl)(N^{iPr}-amd) pulse time in seconds;

FIG. 5 is a X-ray Photoelectron Spectroscopy (XPS) graph showing the content of the Ni film deposited from Ni(2-Meallyl)(N^{iPr}-amd) versus etch time in seconds;

FIG. 6 is a cross section view from a Scanning Electron Microscope (SEM) photograph of the Ni film deposited from Ni(2-Meallyl)(N^{iPr}-amd); and

FIG. 7 is a SEM photograph of the Ni film deposited on a patterned wafer with trenches having an aspect ratio of 2.

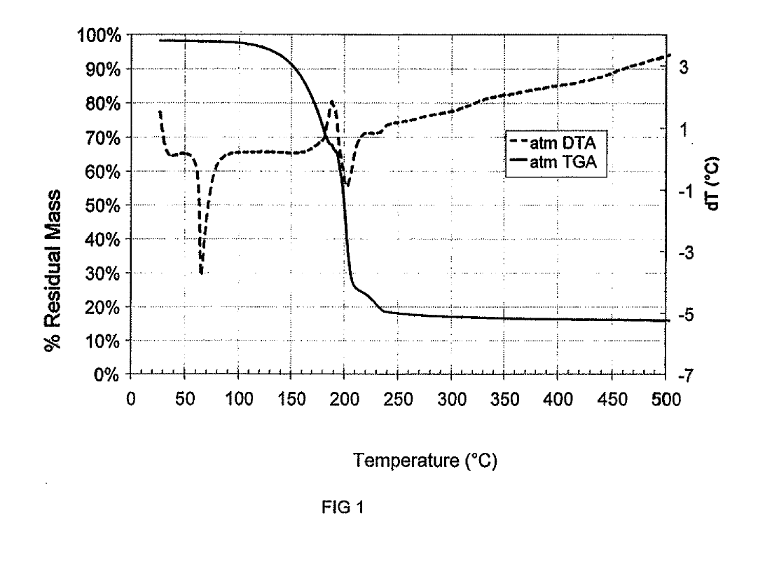

### DESCRIPTION OF PREFERRED EMBODIMENTS

Disclosed are nickel-containing precursors having the formula:

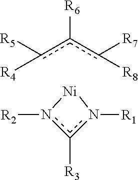

wherein each of R₁, R₂, R₃, R₄, R₅, R₆, R₇, and R₈ are independently selected from H; a C1-C4 linear or branched alkyl group; a C1-C4 linear or branched alkylsilyl group (mono, bis, or tris alkyl); a C1-C4 linear or branched alkylamino group; or a C1-C4 linear or branched fluoroalkyl group.

As illustrated above, the anionic amidinate ligand is bonded to the nickel atom through its two nitrogen atoms, whereas all three carbons in the anionic allyl ligand are bonded to the Ni atom through the electrons in the floating double bond (η3 bonding). The combination of the two ligands provides a stable yet volatile nickel-containing precursor suitable for use in vapor deposition of nickel-containing films.

Exemplary nickel-containing precursors include but are not limited to:

η3-allyl N,N′-dimethylacetamidinate;

η3-allyl N,N′-diethylacetamidinate;

η3-allyl N,N′-diisopropylacetamidinate;

η3-allyl N,N′-di-n-propylacetamidinate;

η3-allyl N,N′-di-tertbutylacetamidinate;

η3-allyl N,N′-ethyl,tertbutylacetamidinate;

η3-allyl N,N′-ditrimethylsilylacetamidinate;

η3-allyl N,N′-diisopropylguanidinate;

η3-allyl N,N′-diisopropylformamidinate;

η3-1-methylallyl N,N′-dimethylylacetamidinate;

η3-1-methylallyl N,N′-diethylylacetamidinate;

η3-1-methylallyl N,N′-diisopropylacetamidinate;

η3-1-methylallyl N,N′-di-n-propylacetamidinate;

η3-1-methylallyl N,N′-di-tertbutylacetamidinate;

η3-1-methylallyl N,N′-ethyl,tertbutylacetamidinate;

η3-1-methylallyl N,N′-ditrimethylsilylacetamidinate;

η3-1-methylallyl N,N′-diisopropylguanidinate;

η3-1-methylallyl N,N′-diisopropylformamidinate;

η3-2-methylallyl N,N′-dimethylylacetamidinate;

η3-2-methylallyl N,N′-diethylylacetamidinate;

η3-2-methylallyl N,N′-diisopropylacetamidinate;

η3-2-methylallyl N,N′-di-n-propylacetamidinate;

η3-2-methylallyl N,N′-di-tertbutylacetamidinate;

η3-2-methylallyl N,N′-ethyl,tertbutylacetamidinate;

η3-2-methylallyl N,N′-ditrimethylsilylacetamidinate;

η3-2-methylallyl N,N′-diisopropylguanidinate; and

η3-2-methylallyl N,N′-diisopropylformamidinate.

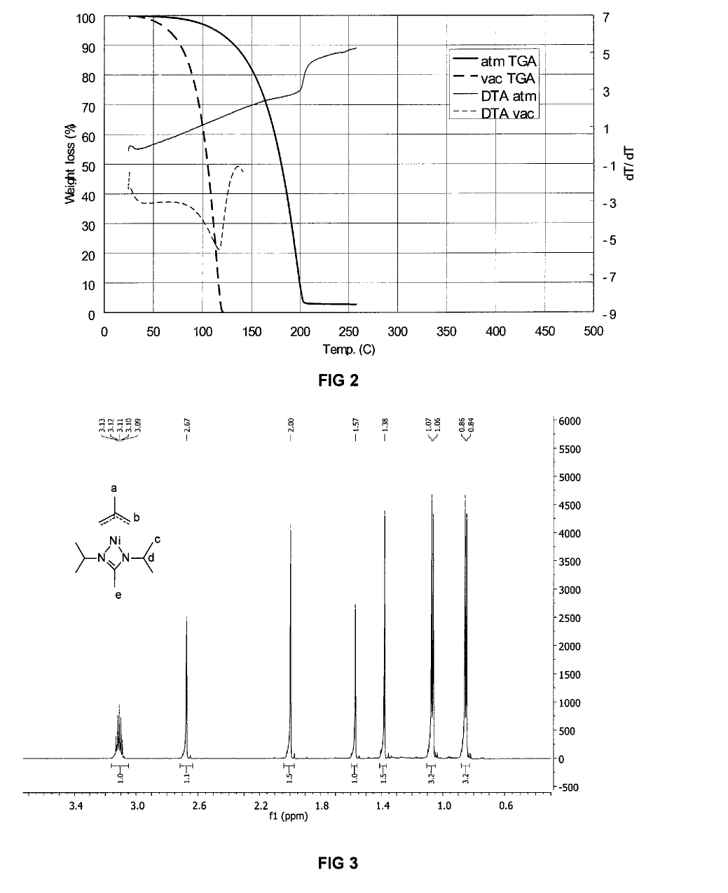

Preferably, the nickel-containing precursor is η3-2-methylallyl N,N′-diisopropylacetamidinate nickel (II) (with R₁ and R₂=iPr; R₃ and R₆=Me; and R₄, R₅, R₇, and R₈═H in the formula above) due to its excellent vaporization results in atmospheric thermogravimetric analysis, leaving a small amount of final residue (see FIG. 2).

The disclosed nickel-containing precursors may be synthesized by reacting lithium amidinate with nickel allyl chloride in a suitable solvent, such as THF and hexane. An exemplary synthesis method containing further details is provided in the Examples that follow.

Also disclosed are methods for forming a nickel-containing layer on a substrate using a vapor deposition process. The method may be useful in the manufacture of semiconductor, photovoltaic, LCD-TFT, or flat panel type devices. The disclosed nickel-containing precursors may be used to deposit thin nickel-containing films using any deposition methods known to those of skill in the art. Examples of suitable deposition methods include without limitation, conventional chemical vapor deposition (CVD), plasma enhanced chemical vapor deposition (PECVD), low pressure chemical vapor deposition (LPCVD), plasma enhanced chemical vapor depositions (PECVD), atomic layer deposition (ALD), pulsed chemical vapor deposition (PCVD), plasma enhanced atomic layer deposition (PEALD), or combinations thereof.

The disclosed nickel-containing precursors may be supplied either in neat form or in a blend with a suitable solvent, such as ethyl benzene, xylene, mesitylene, decane, dodecane. The disclosed precursors may be present in varying concentrations in the solvent.

One or more of the neat or blended nickel-containing precursors are introduced into a reactor in vapor form by conventional means, such as tubing and/or flow meters. The precursor in vapor form may be produced by vaporizing the neat or blended precursor solution through a conventional vaporization step such as direct vaporization, distillation, or by bubbling. The neat or blended precursor may be fed in liquid state to a vaporizer where it is vaporized before it is introduced into the reactor. Alternatively, the neat or blended precursor may be vaporized by passing a carrier gas into a container containing the precursor or by bubbling the carrier gas into the precursor. The carrier gas may include, but is not limited to, Ar, He, N₂, and mixtures thereof. Bubbling with a carrier gas may also remove any dissolved oxygen present in the neat or blended precursor solution. The carrier gas and precursor are then introduced into the reactor as a vapor.

If necessary, the container of disclosed precursor may be heated to a temperature that permits the precursor to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of precursor vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates onto which the thin films will be deposited. The one or more substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step.

The temperature and the pressure within the reactor are held at conditions suitable for ALD or CVD depositions. In other words, after introduction of the vaporized precursor into the chamber, conditions within the chamber are such that at least part of the vaporized precursor is deposited onto the substrate to form a nickel-containing film. For instance, the pressure in the reactor may be held between about 1 Pa and about 10⁵ Pa, more preferably between about 25 Pa and about 10³ Pa, as required per the deposition parameters. Likewise, the temperature in the reactor may be held between about 100° C. and about 500° C., preferably between about 150° C. and about 350° C.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 100° C. to approximately 500° C. When a plasma deposition process is utilized, the deposition temperature may range from approximately 150° C. to approximately 350° C. Alternatively, when a thermal process is performed, the deposition temperature may range from approximately 200° C. to approximately 500° C.

In addition to the disclosed precursor, a reactant may also be introduced into the reactor. The reactant may be an oxidizing gas such as one of O₂, O₃, H₂O, H₂O₂, oxygen containing radicals such as O. or OH., NO, NO₂,carboxylic acids, formic acid, acetic acid, propionic acid, and mixtures thereof. Preferably, the oxidizing gas is selected from the group consisting of O₂, O₃, H₂O, H₂O₂, oxygen containing radicals thereof such as O. or OH., and mixtures thereof. Alternatively, the reactant may be a reducing gas such as one of H₂, NH₃, SiH₄, Si₂H₆, Si₃H₈, (CH₃)₂SiH₂, (C₂H₅)₂SiH₂, (CH₃)SiH₃, (C₂H₅)SiH₃, phenyl silane, N₂H₄, N(SiH₃)₃, N(CH₃)H₂, N(C₂H₅)H₂, N(CH₃)₂H, N(C₂H₅)₂H, N(CH₃)₃, N(C₂H₅)₃, (SiMe₃)₂NH, (CH₃)HNNH₂, (CH₃)₂NNH₂, phenyl hydrazine, N-containing molecules, B₂H₆, 9-borabicyclo[3,3,1]nonane, dihydrobenzenfuran, pyrazoline, trimethylaluminium, dimethylzinc, diethylzinc, radical species thereof, and mixtures thereof. Preferably, the reducing as is H₂, NH₃, SiH₄, Si₂H₆, Si₃H₈, SiH₂Me₂, SiH₂Et₂, N(SiH₃)₃, hydrogen radicals thereof, or mixtures thereof.

The reactant may be treated by a plasma, in order to decompose the reactant into its radical form. N₂ may also be utilized as a reducing gas when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

The vapor deposition conditions within the chamber allow the disclosed precursor and the reactant to react and form a nickel-containing film on the substrate. In some embodiments, Applicants believe that plasma-treating the reactant may provide the reactant with the energy needed to react with the disclosed precursor.

Depending on what type of film is desired to be deposited, a second precursor may be introduced into the reactor. The second precursor may be used to provide additional elements to the nickel-containing film. The additional elements may include copper, praseodymium, manganese, ruthenium, titanium, tantalum, bismuth, zirconium, hafnium, lead, niobium, magnesium, aluminum, lanthanum, or mixtures of these. When a second precursor is utilized, the resultant film deposited on the substrate may contain nickel in combination with at least one additional element.

The nickel-containing precursors and reactants may be introduced into the reactor either simultaneously (chemical vapor deposition), sequentially (atomic layer deposition) or different combinations thereof. The reactor may be purged with an inert gas between the introduction of the precursor and the introduction of the reactant. Alternatively, the reactant and the precursor may be mixed together to form a reactant/precursor mixture, and then introduced to the reactor in mixture form. Another example is to introduce the reactant continuously and to introduce the at least one nickel-containing precursor by pulse (pulsed chemical vapor deposition).

The vaporized precursor and the reactant may be pulsed sequentially or simultaneously (e.g. pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reactant may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of the disclosed nickel-containing precursor and a reactant are simultaneously introduced into the reactor. The two react to form the resulting nickel-containing thin film. When the reactant in this exemplary CVD process is treated with a plasma, the exemplary CVD process becomes an exemplary PECVD process. The reactant may be treated with plasma prior or subsequent to introduction into the chamber.

In one non-limiting exemplary ALD type process, the vapor phase of the disclosed nickel-containing precursor is introduced into the reactor, where it is contacted with a suitable substrate. Excess precursor may then be removed from the reactor by purging and/or evacuating the reactor. A reducing gas (for example, H₂) is introduced into the reactor where it reacts with the absorbed precursor in a self-limiting manner. Any excess reducing gas is removed from the reactor by purging and/or evacuating the reactor. If the desired film is a nickel film, this two-step process may provide the desired film thickness or may be repeated until a film having the necessary thickness has been obtained.

Alternatively, if the desired film contains nickel and a second element, the two-step process above may be followed by introduction of the vapor of a second precursor into the reactor. The second precursor will be selected based on the nature of the nickel film being deposited. After introduction into the reactor, the second precursor is contacted with the substrate. Any excess second precursor is removed from the reactor by purging and/or evacuating the reactor. Once again, a reducing gas may be introduced into the reactor to react with the second precursor. Excess reducing gas is removed from the reactor by purging and/or evacuating the reactor. If a desired film thickness has been achieved, the process may be terminated. However, if a thicker film is desired, the entire four-step process may be repeated. By alternating the provision of the nickel-containing precursor, second precursor, and reactant, a film of desired composition and thickness can be deposited.

When the reactant in this exemplary ALD process is treated with a plasma, the exemplary ALD process becomes an exemplary PEALD process. The reactant may be treated with plasma prior or subsequent to introduction into the chamber.

The nickel-containing films resulting from the processes discussed above may include a pure nickel (Ni), nickel silicide (NiₖSiₗ), or nickel oxide (NiₙOₘ) film wherein k, l, m, and n are integers which inclusively range from 1 to 6. One of ordinary skill in the art will recognize that by judicial selection of the appropriate disclosed precursor, optional second precursors, and reactant species, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the nickel-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the nickel-containing film. This in turn tends to improve the resistivity of the film.

After annealing, the nickel-containing films deposited by any of the disclosed processes have a bulk resistivity at room temperature of approximately 7 μohm·cm to approximately 70 μohm·cm, preferably approximately 7 μohm·cm to approximately 20 μohm·cm, and more preferably approximately 7 μohm·cm to approximately 12 μohm·cm. Room temperature is approximately 20° C. to approximately 28° C. depending on the season. Bulk resistivity is also known as volume resistivity. One of ordinary skill in the art will recognize that the bulk resistivity is measured at room temperature on Ni films that are typically approximately 50 nm thick. The bulk resistivity typically increases for thinner films due to changes in the electron transport mechanism. The bulk resistivity also increases at higher temperatures.

### EXAMPLES

The following examples illustrate experiments performed in conjunction with the disclosure herein. The examples are not intended to be all inclusive and are not intended to limit the scope of disclosure described herein.

### Example 1

### η3-2-methylallyl N,N′-diisopropylacetamidinate Synthesis

In a 1 L 3-neck flask under nitrogen, 32.4 g (250 mmol) of NiCl₂ was introduced with THF (˜200 mL). 500 mL (250 mmol) of 2-methylallylmagnesium chloride (0.5M in THF) was introduced at 0° C. and the mixture stirred overnight. A dark brown solution with brown suspension consisting of [Ni(2-Meallyl)Cl]₂ was formed.

N,N′ diisopropylcarbodiimide 31.5 g (250 mmol) was introduced into another 1 L 3-neck flask under nitrogen. 235.8 mL (250 mmol) of MeLi (1.06 M in ether) was introduced at −78° C. and the mixture stirred overnight at room temperature. The Li-iPrAMD solution was added to the [Ni(2Meallyl)Cl]₂ suspension and the mixture stirred overnight at room temperature. A dark solution was formed.

Solvent was then removed under vacuum and toluene added (300 mL). The solution was filtered over Celite brand diatomaceous earth and the toluene removed under vacuum to give a dark sticky material. Pentane was added (300 mL). The solution was filtered over Celite brand diatomaceous earth and the pentane removed under vacuum to give a dark orange liquid. The material was purified by distillation at 88° C. @ 200-300 mTorr (bp˜69-71° C.) to give 38.6 g (152 mmol, 61%) of an orange liquid consisting of nickel η3-2-methylallyl N,N′-diisopropylacetamidinate.

The orange liquid left a <5% residual mass during TGA analysis measured at a temperature rising rate of 10° C./min in an atmosphere which flows nitrogen at 220 mL/min. These results are depicted in FIG. 2, which is a TGA graph demonstrating the percentage of weight loss with temperature change. The NMR1H spectrum is provided in FIG. 3.

NMR1H (δ, ppm, C6D6): 3.11 (sp, 2H), 2.67 (s, 2H), 2.00 (s, 3H), 1.57 (s, 2H), 1.38 (s, 3H), 1.06 (d, 6H), 0.84 (d, 6H)

### Example 2

### PEALD of Pure Nickel

PEALD tests were performed using the η3-2-methylallyl N,N′-diisopropylacetamidinate prepared in Example 1, which was placed in a vessel heated up to 50° C. Typical PEALD conditions were used, such as using hydrogen and/or ammonia plasma with a reactor pressure fixed at ˜2 Torr and plasma power optimized to 100 W to provide a complete reaction and limit impurities incorporation in the resulting film. ALD behavior with complete surface saturation and reaction was assessed in a temperature window of 200-350° C. on pure silicon wafers.

In limited testing, the films produced using hydrogen plasma contained more impurities than the films produced using ammonia plasma. Limited testing also revealed that a longer reactant pulse time or higher plasma power produced a flat film with higher growth per cycle and lower resistivity, but resulted in higher carbon content. Ongoing testing is being conducted to determine optimum conditions.

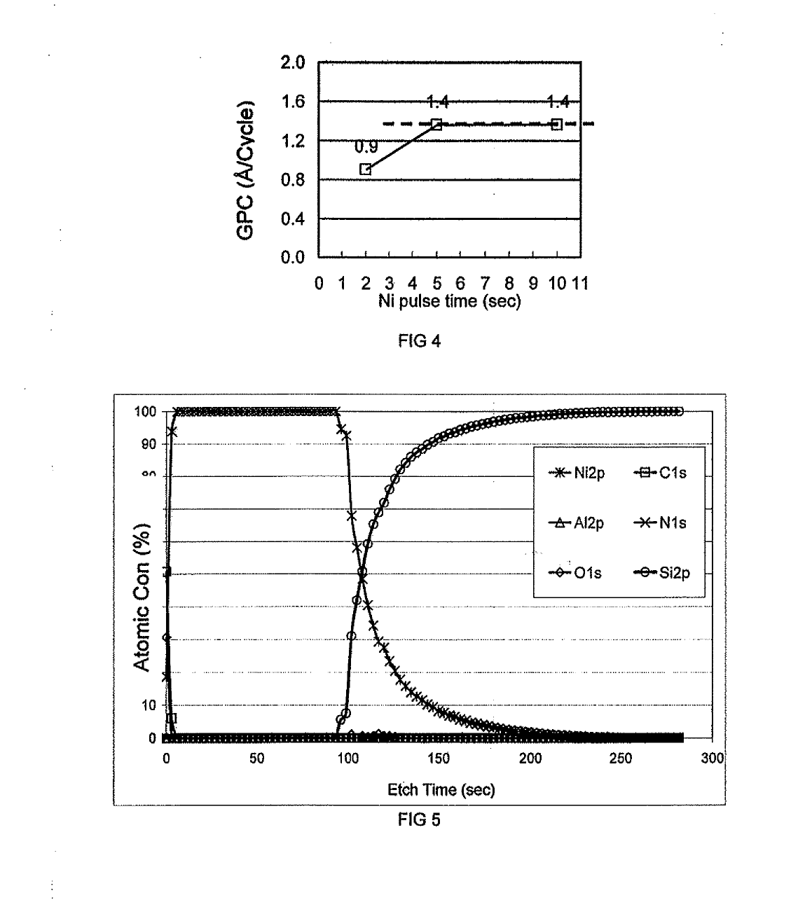

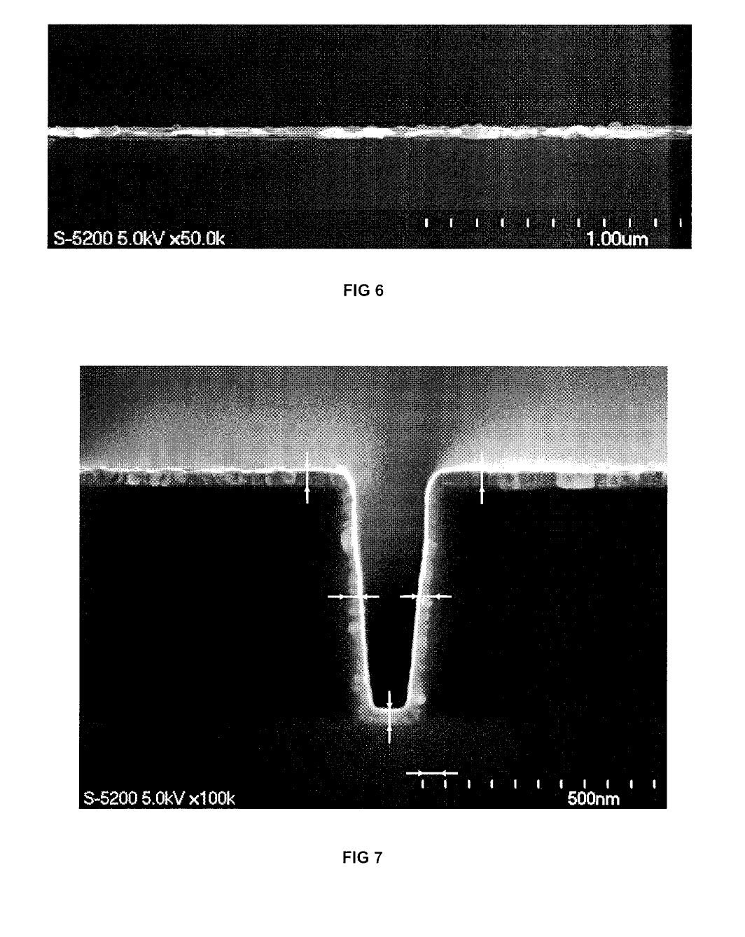

A deposition rate as high as 1.4 Å/cycle was obtained at 300° C. using ammonia plasma (see FIG. 4). After annealing the film at 400° C. with hydrogen for 1 hour, X-ray Photoelectron Spectroscopy (XPS) showed no carbon or nitrogen incorporation into the film, the purity of the nickel film being closed to 100% (see FIG. 5). No silicidation was observed at the interface of the Ni film and silicon wafer. The Scanning Electron Microscope (SEM) showed a surface (˜41 nm thick) with uniform and smooth grains, and with good continuity (see FIG. 6). Resistivity as low as ˜9μΩ·cm were obtained for 41 nm thick nickel film which is close to the bulk resistivity of nickel. Depositions performed on a patterned wafer with trenches having an aspect ratio of 2 allowed the formation of a Ni film with a conformality close to 100% (see FIG. 7).

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. A nickel-containing precursor having the formula: 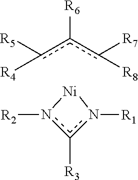
wherein each of R₁, R₂, R₃, R₄, R₅, R₆, R₇, and R₈ are independently selected from H; a C1-C4 linear, branched, or cyclic alkyl group; a C1-C4 linear, branched, or cyclic alkylsilyl group (mono, his, or tris alkyl); a C1-C4 linear, branched, or cyclic alkylamino group; or a C1-C4 linear, branched, or cyclic fluoroalkyl group.

2. The nickel-containing precursor of claim 1, wherein the nickel-containing precursor is selected from the group consisting of:
η3-allyl N,N′-dimethylacetamidinate;
η3-allyl N,N′-diethylacetamidinate;
η3-allyl N,N′-diisopropylacetamidinate;
η3-allyl N,N′-di-n-propylacetamidinate;
η3-allyl N,N′-di-tertbutylacetamidinate;
η3-allyl N,N′-ethyl,tertbutylacetamidinate;
η3-allyl N,N′-ditrimethylsilylacetamidinate;
η3-allyl N,N′-diisopropylguanidinate;
η3-allyl N,N′-diisopropylformamidinate;
η3-1-methylallyl N,N′-dimethylacetamidinate;
η3-1-methylallyl N,N′-diethylacetamidinate;
η3-1-methylallyl N,N′-diisopropylacetamidinate;
η3-1-methylallyl N,N′-di-n-propylacetamidinate;
η3-1-methylallyl N,N′-di-tertbutylacetamidinate;
η3-1-methylallyl N,N′-ethyl,tertbutylacetamidinate;
η3-1-methylallyl N,N′-ditrimethylsilylacetamidinate;
η3-1-methylallyl N,N′-diisopropylguanidinate;
η3-1-methylallyl N,N′-diisopropylformaimidinate;
η3-2-methylallyl N,N′-dimethylacetamidinate;
η3-2-methylallyl N,N′-diethylacetamidinate;
η3-2-methylallyl N,N′-diisopropylacetamidinate;
η3-2-methylallyl N,N′-di-n-propylacetamidinate;
η3-2-methylallyl N,N′-di-tertbutylacetamidinate;
η3-2-methylallyl N,N′-ethyl,tertbutylacetamidinate;
η3-2-methylallyl N,N′-ditrimethylsilylacetamidinate;
η3-2-methylallyl N,N′-diisopropylguanidinate; and
η3-2-methylallyl N,N′-diisopropylformamidinate.

3. The nickel-containing precursor of claim 2, wherein the nickel-containing precursor is η3-2-methylallyl N,N′-diisopropylacetamidinate.

4. A process for the deposition of a nickel-containing film on a substrate, comprising the steps of;
introducing at least one nickel-containing precursor into a reactor having at least one substrate disposed therein, the at least one nickel-containing precursor having the formula: 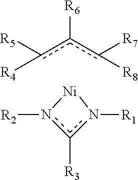
wherein each of R₁, R₂, R₃, R₄, R₅, R₆, R₇, and R₈ are independently selected from H; a C1-C4 linear, branched, or cyclic alkyl group; a C1-C4 linear, branched, or cyclic alkylsilyl group (mono, bis, or tris alkyl); a C1-C4 linear, branched, or cyclic alkylamino group; or a C1-C4 linear, branched, or cyclic fluoroalkyl group; and
depositing at least part of the nickel-containing precursor onto the at least one substrate to form the nickel-containing film.

5. The process of claim 4, further comprising introducing at least one reactant into the reactor.

6. The process of claim 5, wherein the reactant is selected from the group consisting of H₂, NH₃, SiH₄, Si₂H₆, Si₃H₈, SiH₂Me₂, SiH₂Et₂, N(SiH₃)₃, hydrogen radicals thereof; and mixtures thereof.

7. The process of claim 5, wherein the reactant is selected from the group consisting of: O₂, O₃, H₂O, NO, N₂O, oxygen radicals thereof; and mixtures thereof.

8. The process of claim 5, wherein the nickel-containing precursor and the reactant are introduced into the reactor substantially simultaneously and the reactor is configured for chemical vapor deposition.

9. The process of claim 8, wherein the reactor is configured for plasma enhanced chemical vapor deposition.

10. The process of claim 5, wherein the nickel-containing precursor and the reactant are introduced into the chamber sequentially and the reactor is configured for atomic layer deposition.

11. The process of claim 10, wherein the reactor is configured for plasma enhanced atomic layer deposition.

12. The process of claim 4, wherein the nickel-containing precursor is selected from the group consisting of:
η3-allyl N,N′-dimethylacetamidinate;
η3-allyl N,N′-diethylacetamidinate;
η3-allyl N,N′-diisopropylacetamidinate;
η3-allyl N,N′-di-n-propylacetamidinate,
η3-allyl N,N′-di-tertbutylacetamidinate;
η3-allyl N,N′-ethyl,tertbutylacetamidinate;
η3-allyl N,N′-ditrimethylsilylacetamidinate;
η3-allyl N,N′-diisopropylguanidinate;
η3-allyl N,N′-diisopropylformamidinate;
η3-1-methylallyl N,N′-dimethylacetamidinate;
η3-1-methylallyl N,N′-diethylacetamidinate;
η3-1-methylallyl N,N′-diisopropylacetamidinate;
η3-1-methylallyl N,N′-di-n-propylacetamidinate;
η3-1-methylallyl N,N′-di-tertbutylacetamidinate;
η3-1-methylallyl N,N′-ethyl,tertbutylacetamidinate;
η3-1-methylallyl N,N′-ditrimethylsilylacetamidinate;
η3-1-methylallyl N,N′-diisopropylguanidinate;
η3-1-methylallyl N,N′-diisopropylformamidinate;
η3-2-methylallyl N,N′-dimethylacetamidinate;
η3-2-methylallyl N,N′-diethylacetamidinate;
η3-2-methylallyl N,N′-diisopropylacetamidinate;
η3-2-methylallyl N,N′-di-n-propylacetamidinate;
η3-2-methylallyl N,N′-di-tertbutylacetamidinate;
η3-2-methylallyl N,N′-ethyl,tertbutylacetamidinate;
η3-2-methylallyl N,N′-ditrimethylsilylacetamidinate;
η3-2-methylallyl N,N′-diisopropylguanidinate; and
η3-2-methylallyl N,N′-diisopropylformamidinate.

13. The process of claim 12, wherein the nickel-containing precursor is η3-2-methylallyl N,N′-diisopropylacetamidinate.

14. The process of claim 13, further comprising annealing the nickel-containing film.

15. The process of claim 14, wherein the annealed nickel-containing film is an approximately 100% pure Ni film.

16. The process of claim 14, wherein the pure Ni film contains no carbon or nitrogen.

17. A nickel-containing film deposited by the process of claim 14, in which the resistivity is approximately 7 μohm·cm to approximately 70 μohm·cm.
